(19) United States
(12) Patent Application Publication
(10) Pub. No.: US 2024/0289417 A1
(43) Pub. Date: Aug. 29, 2024

(54) CALCULATION METHOD, CALCULATION DEVICE, AND NON-TRANSITORY TANGIBLE COMPUTER-READABLE STORAGE MEDIUM

(71) Applicant: Sumitomo Electric Industries, Ltd., Osaka (JP)

(72) Inventor: Takeshi KAWASAKI, Osaka-shi (JP)

(73) Assignee: Sumitomo Electric Industries, Ltd., Osaka (JP)

(21) Appl. No.: 18/405,219

(22) Filed: Jan. 5, 2024

(30) Foreign Application Priority Data
Feb. 27, 2023 (JP) 2023-028592

(51) Int. Cl. G06F 17/16

(52) U.S. Cl. CPC G06F 17/16

(57) ABSTRACT

A calculation method is executed by a computer to execute a process. The process includes acquiring a condition for calculating a first matrix of a reactance circuit having N ports Pi to which a high frequency signal is input or output, wherein i is an integer of 1 to N, and N is an integer of 2 or more, and calculating, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij).

### CROSS REFERENCE TO RELATED APPLICATIONS

This application claims priority based on Japanese Patent Application No. 2023-028592 filed on Feb. 27, 2023, and the entire contents of the Japanese patent applications are incorporated herein by reference.

### FIELD

The present disclosure relates to a calculation method, a calculation device, and a non-transitory tangible computer-readable storage medium.

### BACKGROUND

A reactance circuit using reactance elements such as an inductor and a capacitor is used as a matching circuit such as an amplifier circuit (for example, Patent Document 1: Japanese Laid-open Patent Publication No. 2022-174987).

### SUMMARY

A calculation method according to the present disclosure is executed by a computer to execute a process. The process includes acquiring a condition for calculating a first matrix of a reactance circuit having N ports Pi to which a high frequency signal is input or output, wherein i is an integer of 1 to N, and N is an integer of 2 or more, and calculating, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij).

The present disclosure can be realized not only as such a characteristic calculation method but also as a calculation device and a computer-readable storage medium for processing such characteristic steps. The present disclosure may be realized as a semiconductor integrated circuit that realizes a part or all of the calculation device, or may be realized as a calculation system including the calculation device.

### BRIEF DESCRIPTION OF DRAWINGS

FIG. 1 is a block diagram of a reactance circuit for calculating circuit parameters according to a first embodiment.

FIG. 2 is a block diagram of a computer according to the first embodiment.

FIG. 3 is a functional block diagram of a calculation device according to a first embodiment.

FIG. 4 is a flowchart illustrating a calculation method for extracting the circuit parameters according to the first embodiment.

FIG. 5 is a flowchart illustrating a method for optimizing an admittance matrix according to the first embodiment.

FIG. 6 is a circuit diagram illustrating a circuit example A of a reactance circuit.

FIG. 7 is a circuit diagram illustrating a circuit example B of the reactance circuit.

FIG. 8 is a circuit diagram of a sub-reactance circuit in the circuit example B.

FIG. 9 is a flowchart illustrating a method for optimizing the circuit parameters according to the first embodiment.

FIG. 10 is a circuit diagram illustrating a Doherty amplifier circuit according to a second embodiment.

FIG. 11 is a block diagram of a matching circuit for calculating the circuit parameters according to the second embodiment.

FIG. 12 is a schematic diagram illustrating an output power Pout and a drain efficiency Eff with respect to an input power Pin of the Doherty amplifier according to the second embodiment.

FIG. 13 is a diagram illustrating an example of an admittance matrix output in step S14 of FIG. 4.

FIG. 14 is a diagram illustrating an example in which the admittance matrix of FIG. 13 is converted into a scattering matrix.

### DETAILED DESCRIPTION OF EMBODIMENTS

The design of the reactance circuit is optimized by changing the connection relationship and the element values of the reactance elements so that the characteristic of an electronic circuit including the reactance circuit have a desired value. However, since there are an infinite number of connection relationships and element values of the reactance elements, an algorithm for calculating the circuit parameters of the reactance circuit is complicated. In addition, there are cases where the circuit parameters of the reactance circuit become local solutions and cannot be optimized.

The present disclosure has been made in view of the above problems, and it is an object of the present disclosure to easily design a reactance circuit.

### Details of Embodiments of the Present Disclosure

First, the contents of the embodiments of this disclosure are listed and explained.

(1) A calculation method according to the present disclosure is executed by a computer to execute a process. The process includes acquiring a condition for calculating a first matrix of a reactance circuit having N ports Pi to which a high frequency signal is input or output, wherein i is an integer of 1 to N, and N is an integer of 2 or more, and calculating, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij). This enables easy design of the reactance circuit.

(2) In the above (1), Γij=Γji may be satisfied in the first matrix. This can reduce the number of parameters of the first matrix to be calculated.

(3) In the above (1) or (2), in the calculating the first matrix, the first matrix may be calculated by optimizing the first matrix with the condition as an objective function. This allows the first matrix to be optimized.

(4) In any one of the above (1) to (3), the calculation method further may include calculating a circuit parameter of the reactance circuit based on a calculated first matrix. This can suppress the algorithm for calculating the circuit parameters from becoming more complex.

(5) In the above (4), in sub-reactance circuits each having a first end connected to a port Pi and a second end connected to a common node, the circuit parameter may include a number of one or more reactance elements alternately series-connected and shunt-connected between the first end and the second end and a reactance value of the one or more reactance elements. This can reduce the number of circuit parameters.

(6) In any one of the above (1) to (5), the reactance circuit may be a matching circuit used in an amplifier circuit. This enables the matching circuit to be designed with high accuracy.

(7) In the above (6), the first matrix may include a first matrix related to a fundamental wave which has a frequency within an operating band of the amplifier circuit. The calculation method further may include calculating a second matrix related to a harmonic of the frequency. The second matrix may have elements that are 0 and other than diagonal elements, and the second matrix may include an admittance matrix, an impedance matrix, or a scattering matrix. This enables calculation of the circuit parameters in consideration of the harmonic.

(8) In any one of the above (1) to (7), the first matrix may be the admittance matrix. This allows the port to be treated as open to ground.

(9) A calculation device according to the present disclosure includes a memory, and a processor coupled to the memory. The processor configured to acquire a condition for calculating a first matrix of a reactance circuit having N ports Pi to which a high frequency signal is input or output, wherein i is an integer of 1 to N, and N is an integer of 2 or more; and calculate, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij). This enables easy design of the reactance circuit.

(10) In the above (9), Γij=Γji may be satisfied in the first matrix. This can reduce the number of parameters of the first matrix to be calculated.

(11) In the above (9) or (10), the processor may calculate the first matrix by optimizing the first matrix with the condition as an objective function. This allows the first matrix to be optimized.

(12) In any one of the above (9) to (11), the processor may calculate a circuit parameter of the reactance circuit based on a calculated first matrix. This can suppress the algorithm for calculating the circuit parameters from becoming more complex.

(13) In the above (12), in sub-reactance circuits each having a first end connected to a port Pi and a second end connected to a common node, the circuit parameter may include a number of one or more reactance elements alternately series-connected and shunt-connected between the first end and the second end and a reactance value of the one or more reactance elements. This can reduce the number of circuit parameters.

(14) In any one of the above (9) to (13), the reactance circuit may be a matching circuit used in an amplifier circuit. This enables the matching circuit to be designed with high accuracy.

(15) In the above (14), the first matrix may include a first matrix related to a fundamental wave which has a frequency within an operating band of the amplifier circuit. The processor may calculate a second matrix related to a harmonic of the frequency. The second matrix may have elements that are 0 and other than diagonal elements, and the second matrix may include an admittance matrix, an impedance matrix, or a scattering matrix. This enables calculation of the circuit parameters in consideration of the harmonic.

(16) In any one of the above (9) to (15), the first matrix may be the admittance matrix. This allows the port to be treated as open to ground.

(17) The present disclosure includes a non-transitory tangible computer-readable storage medium having stored therein a program for causing a computer to execute a process. The process includes acquiring a condition for calculating a first matrix of a reactance circuit having N ports Pi to which a high frequency signal is input or output, wherein i is an integer of 1 to N, and N is an integer of 2 or more, and calculating, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij). This enables easy design of the reactance circuit.

Specific examples of a calculation method, a calculation device, and a non-transitory tangible computer-readable storage medium according to embodiments of the present disclosure will be described below with reference to the drawings. It should be noted that the present disclosure is not limited to these examples, but is defined by the claims and is intended to include all modifications within the meaning and scope equivalent to the claims.

At least some of the embodiments described below may be combined in any manner. The calculation device includes a computer, and each function of the calculation device is exhibited by a computer program stored in a storage device of the computer and executed by a CPU (Central Processing Unit) of the computer. The computer program can be stored in a storage medium such as a CD-ROM (Compact Disc Read Only Memory) or a DVD (Digital Versatile Disc).

### [Design of Reactance Circuit]

A reactance circuit is a lossless circuit and is a circuit formed only by reactance elements. Each reactance element is an element having almost no resistance component in an impedance of an inductor, a capacitor, a transmission line, or the like. The circuit design of the reactance circuit is performed such that circuit parameters such as the connection relationship of one or a plurality of reactance elements in the reactance circuit and the element values of the reactance elements are optimized and the characteristic of the reactance circuit or the electronic circuit including the reactance circuit are set to a target characteristic. For example, a scattering matrix (S-parameter) is often used in circuit design of a microwave (300 MHz to 30 GHz) or a millimeter wave (30 GHz to 300 GHz).

However, a S parameter is expressed by the power of the high frequency signal input to each port and the power of the high frequency signal output from each port. Therefore, the S parameter cannot be expressed using the resistance and reactance components (or the conductance and susceptance components), and the reactance circuit may not be appropriately expressed using the S parameter. Therefore, in the following embodiments, an admittance matrix (Y parameter) that can be expressed using conductance components and susceptance components is used. In addition to the Y parameter, an impedance matrix (Z parameter) expressed using the resistance component and the reactance component may be used.

### First Embodiment

A calculation method for extracting the admittance matrix and the circuit parameters of the reactance circuit according to the first embodiment will be described below.

### [Description of Reactance Circuit]

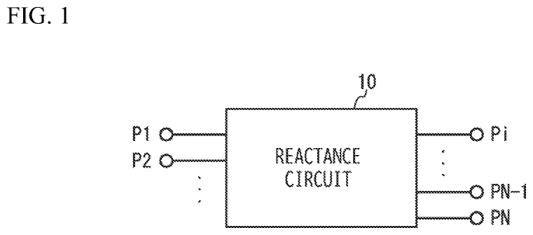

FIG. 1 is a block diagram of a reactance circuit for calculating the circuit parameters according to the first embodiment. As illustrated in FIG. 1, a reactance circuit 10 includes a plurality of ports P1, P2, Pi to PN−1, PN through which high frequency signals are input or output. Here, N is an integer corresponding to the number of ports P1 to PN of the reactance circuit 10, and is 2 or more. “i” in FIG. 1 is an integer from 1 to N. A calculation method for optimizing the admittance matrix and the circuit parameters of the reactance circuit 10 of FIG. 1 will be described below.

### [Block Diagram of Computer]

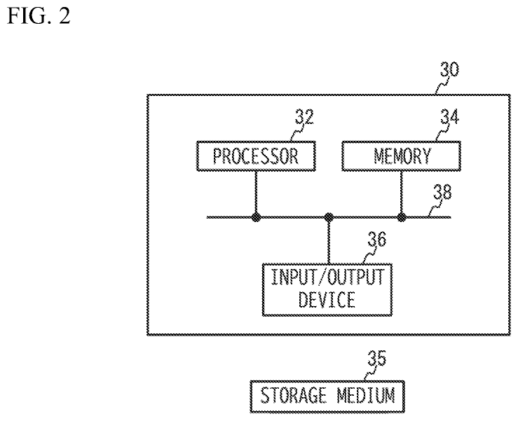

FIG. 2 is a block diagram of a computer according to the first embodiment. A computer 30, in cooperation with software, functions as a computing device for computing the admittance matrix and circuit parameters of the reactance circuit 10. The computer 30 executes a calculation program to execute a calculation method.

The computer 30 includes a processor 32, a memory 34, an input/output device 36, and an internal bus 38. The processor 32 is, for example, a CPU (Central Processing Unit), and executes the calculation program and the calculation method using an equivalent circuit model of the distributed constant circuit. The memory 34 is, for example, a volatile memory or a nonvolatile memory, and stores data and the like used when the processor 32 executes the calculation program and the calculation method. The memory 34 may store a calculation program executed by the processor 32. The input/output device 36 receives data acquired by the processor 32 from an external device and outputs data output by the processor 32 to the external device. The external device may be another computer or another program in the same computer. The internal bus 38 connects the processor 32, the memory 34, and the input/output device 36 to each other, and transmits data and the like. The calculation program is stored in a storage medium 35. The storage medium 35 is a non-transitory tangible medium, for example, and is a CD-ROM or a DVD.

### [Functional Block Diagram]

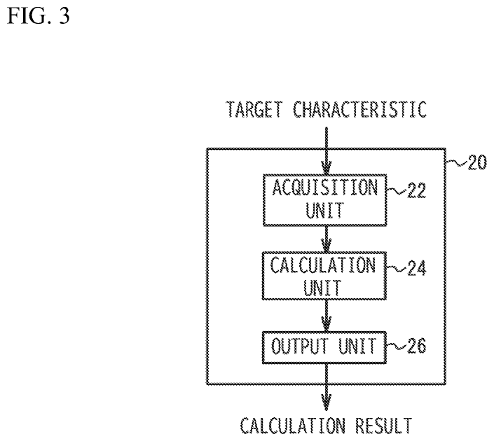

FIG. 3 is a functional block diagram of the calculation device according to the first embodiment. As illustrated in FIG. 3, the calculation device 20 includes an acquisition unit 22, a calculation unit 24, and an output unit 26. The processor 32 cooperates with software and functions as the acquisition unit 22, the calculation unit 24, and the output unit 26. The acquisition unit 22 acquires a condition of calculation and the like from the external device via the input/output device 36. The calculation unit 24 calculates the admittance matrix or the circuit parameters of the reactance circuit 10 based on the condition acquired by the acquisition unit 22. The output unit 26 outputs a result calculated by the calculation unit 24 to the external device via the input/output device 36.

### [Flowchart]

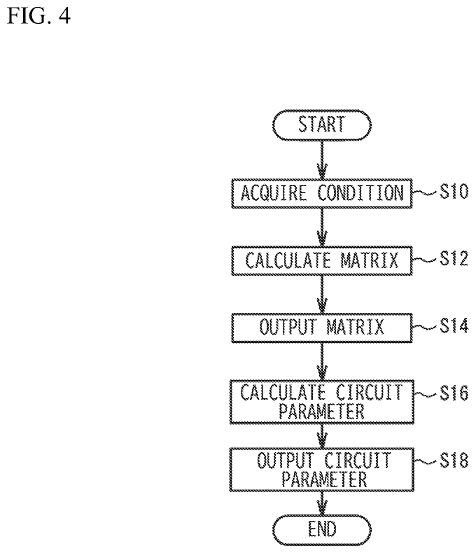

FIG. 4 is a flowchart illustrating a calculation method for extracting the circuit parameters according to the first embodiment. As illustrated in FIG. 4, the acquisition unit 22 acquires the condition (step S10). The condition is, for example, a condition for calculating the number of ports of the reactance circuit 10, the admittance matrix, and the circuit parameters. Then, the calculation unit 24 calculates the admittance matrix based on the acquired condition (step S12). Then, the output unit 26 outputs the calculated admittance matrix to the external device or the memory 34 (step S14). If the circuit parameters are not calculated, the calculation method may be terminated after step S14. Then, the calculation unit 24 calculates the circuit parameters based on the acquired condition and the calculated admittance matrix (step S16). Then, the output unit 26 outputs the calculated circuit parameters to the external device or the memory 34 (step S18). This terminates the calculation method of the admittance matrix and the circuit parameters of the reactance circuit.

### [Method of Optimizing Admittance Matrix]

The admittance matrix of the reactance circuit 10 will be described. Equation 1 is the admittance matrix of the reactance circuit 10.

$$Y = ( \begin{matrix}Y 11 & Y 12 & & … & Y 1 N \\ Y 21 & Y 22 & & … & Y 2 N \\ ⋮ & ⋮ & Yij & ⋱ & ⋮ \\ YN 1 & YN 2 & & … & YNN\end{matrix} ) \qquad [ Equation 1 ]$$

In the admittance matrix, an admittance from the port Pi to the port Pj is taken as an element Yij. In the reactance circuit 10, the conductance components of the respective elements Yij are 0, and only the susceptance components are present. Therefore, the element Yij is represented by Equation 2.

$$Yij = \vert Yij \vert exp ( \pm \frac{π}{2} ) \qquad [ Equation 2 ]$$

The element Yij is an absolute value of Yij and is a real number equal to or greater than 0. A phase in exp (y) corresponds to a phase difference between a voltage and a current in the element Yij. The conductance component of the element Yij is 0. Therefore, the phase Y is +π/2 or −π/2 (i.e., +90° or −90°).

Further, in the reactance circuit, since the input port and the output port are symmetric with each other, Equation 3 is satisfied.

Yij=Yji [Equation 3]

Therefore, the reactance circuit 10 can be expressed by using the element Yij in the broken line of Equation 1. The number of absolute values |Yij| of the element Yij in the broken line of Equation 1 is N(N+1)/2. For N(N+1)/2 elements Yij, one parameter θ is used as a combination such that the phase φ in Equation 2 is +π/2 or −π/2. The parameter θ is 2^{N (N+1)/2} discrete values. The number of parameters expressing the reactance circuit 10 is N(N+1)/2+1.

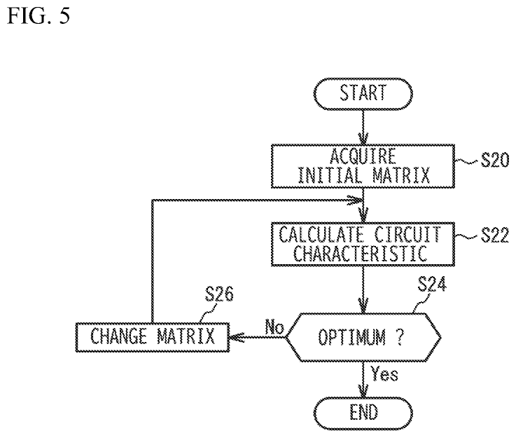

FIG. 5 is a flowchart illustrating a method for optimizing the admittance matrix according to the first embodiment, and corresponds to step S12 in FIG. 4. As illustrated in FIG. 5, the calculation unit 24 acquires an initial admittance matrix (step S20). The initial admittance matrix may be obtained, for example, in step S10 of FIG. 4, or may be stored in advance in the memory 34.

Then, the calculation unit 24 calculates the circuit characteristic (e.g., high frequency characteristic) of the reactance circuit 10 or the electronic circuit including the reactance circuit 10 based on the initial admittance matrix (step S22). The calculated high frequency characteristic (e.g., gain or efficiency of the amplifier circuit) may be acquired in step S10 of FIG. 4, or may be stored in the memory 34 in advance. Thereafter, the calculation unit 24 determines whether the calculated high frequency characteristic is optimal (step S24). For example, in step S10 of FIG. 4, the condition for optimizing the admittance matrix is acquired. If the optimization condition is, for example, a range of the target characteristic of the high frequency characteristic, the calculation unit 24 determines Yes in step S24 when the calculated high frequency characteristic is within the range of the target characteristic, and determines No in step S24 when the calculated high frequency characteristic is outside the range of the target characteristic. If the optimization condition acquired in step S10 of FIG. 4 is that a certain high frequency characteristic is maximum (or minimum), the calculation unit 24 determines Yes in step S24 when the calculated high frequency characteristic is in the maximum (or minimum), and determines No in step S24 when the calculated characteristic is not in the maximum (or minimum).

If step S24 is No, the calculation unit 24 changes the admittance matrix (step S26), and returns to step S22. When the high frequency characteristic calculated in step S22 becomes the target characteristic by repeating steps S22, S24 and S26, the calculation unit 24 determines Yes in step S24. Then, the process is terminated. In steps S22, S24 and S26, a known optimization method such as a Bayesian optimization method may be used, or machine learning may be used. The condition for the optimization of the admittance matrix (e.g., a range of the target characteristic, or a maximum or minimum characteristic) is an objective function of the optimization.

### [Method of Optimizing Circuit Parameter]

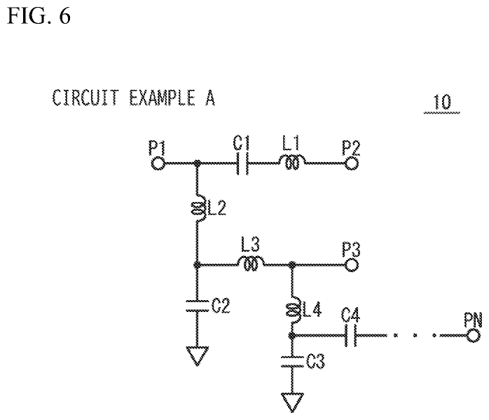

The circuit parameters of the reactance circuit 10 will be described. FIG. 6 is a circuit diagram illustrating a circuit example A of the reactance circuit 10. As illustrated in FIG. 6, in the circuit example A, capacitors C1 to C4 and inductors L1 to L4 are connected between ports P1, P2, P3 and PN, respectively. Thus, in the reactance circuit 10, the plurality of capacitors and the plurality of inductors are connected between the plurality of ports P1 and PN, respectively. In the circuit example A, the circuit parameters are the connection relationship of FIG. 6 and the reactance values (i.e., capacitance and inductance) of the reactance elements.

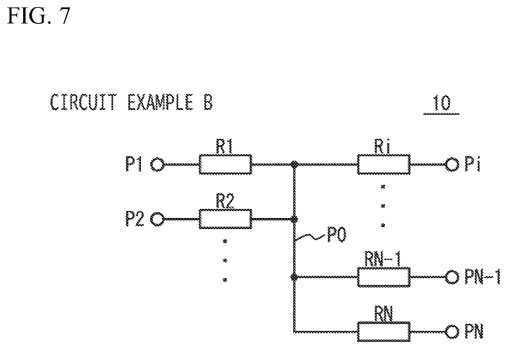

FIG. 7 is a circuit diagram illustrating a circuit example B of the reactance circuit 10. As illustrated in FIG. 7, in the circuit example B, the reactance circuit 10 includes sub-reactance circuits R1, R2 to Ri, Ri to RN−1, and RN. First ends of the sub-reactance circuits Ri to RN are connected to the ports P1 to PN, respectively, and second ends of the sub-reactance circuits R1 to RN are connected to a node P0 in common.

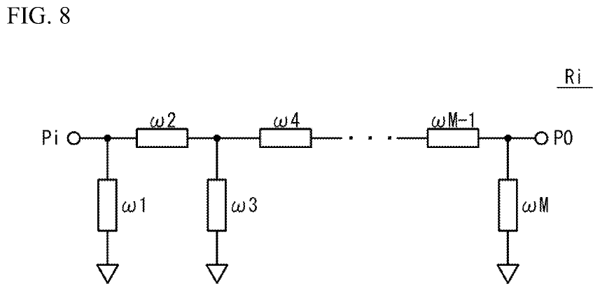

FIG. 8 is a circuit diagram of the sub-reactance circuit in the circuit example B. As illustrated in FIG. 8, the reactance elements ω1, ω3 to ωM are shunt-connected between the port Pi (“i” is an integer of 1 to N) and the node P0. The reactance elements ω2, ω4 to ωM−1 are connected in series between the port Pi and the node P0. The shunt-connected reactance elements ω1, ω3 to ωM and the series-connected reactance elements ω2, ω4 to ωM−1 are alternately provided one by one. In the circuit example B, the circuit parameters are the number M of reactance elements ω1 to ωM in the sub-reactance circuits R1 to RN and the reactance values of the reactance elements ω1 to ωM. When the reactance values of the reactance elements ω1 to ωM are 0 or positive, the reactance elements ω1 to ωM are inductors, and the reactance values are inductances. When the reactance values of the reactance elements ω1 to ωM are negative, the reactance elements co to ωM are capacitors, and the reactance values are capacitances.

In FIG. 8, the reactance element ω1 closest to the port Pi is shunt-connected, but the reactance element co may be series-connected. In FIG. 8, the reactance element ωM closest to the node P0 is shunt-connected, but the reactance element ωM may be series-connected.

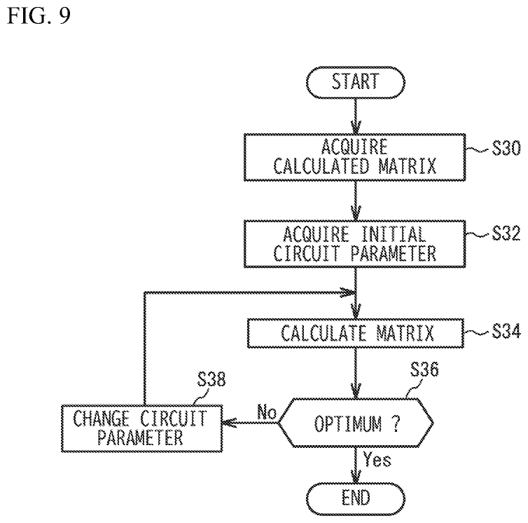

FIG. 9 is a flowchart illustrating a method for optimizing the circuit parameters according to the first embodiment, and corresponds to step S16 in FIG. 4. As illustrated in FIG. 9, the calculation unit 24 acquires the admittance matrix calculated in step S12 of FIG. 4 (step S30). Then, the calculation unit 24 acquires initial circuit parameters (step S32). The initial circuit parameters may be acquired in step S10 of FIG. 4, for example, or may be stored in the memory 34 in advance. The circuit parameters are, for example, the number M of reactance elements ω1 to ωM in the sub-reactance circuits R1 to RN in FIGS. 7 and 8 and the reactance values of the reactance elements ω1 to ωM. The order of steps S30 and S32 may be reversed.

Then, the calculation unit 24 calculates the admittance matrix of the reactance circuit 10 using the initial circuit parameters (step S34). Then, the calculation unit 24 determines whether the admittance matrix calculated in step S34 is optimal (step S36). For example, when the difference between the admittance matrix obtained in step S30 and the admittance matrix calculated in step S34 is determined to be minimum, the calculation unit 24 determines Yes in step S36, and when the above difference is determined not to be minimum, the calculation unit 24 determines No in step S36.

When step S36 is No, the calculation unit 24 changes the circuit parameter (step S38), and the procedure returns to step S34. When the admittance matrix calculated in step S34 substantially matches the admittance matrix obtained in step S30 by repeating steps S34, S36 and S38, the calculation unit 24 determines Yes in step S36. Then, the process is terminated. In steps S34, S36, and S38, an optimization method such as a Bayesian optimization method may be used, or machine learning may be used. The difference between the admittance matrix calculated in step S34 and the admittance matrix obtained in step S30 is the objective function of the optimization.

For example, if the elements of the admittance matrix obtained in step S30 are YAij and the elements of the admittance matrix calculated in step S34 are YBij, the objective function F is expressed by Equation 4.

$$F = \sum \vert Im ( YBij ) - Im ( YAij ) \vert \qquad [ Equation 4 ]$$

Here, Im (YBij) is an imaginary component of YBij, and Im (YAij) is an imaginary component of YAij. Σ is the sum of the elements in the dashed line of Equation 1. The circuit parameters are optimized so that the objective function F is minimized.

In steps S30 and S34 of FIG. 9, the admittance matrix is used as an example of the matrix. The admittance matrix can be uniquely converted into an impedance matrix or a scattering matrix. Therefore, the admittance matrix calculated in step S12 of FIG. 4 is converted into the impedance matrix or the scattering matrix. In step S30, the impedance matrix or the scattering matrix converted from the admittance matrix calculated in step S12 is acquired. In step S34, the impedance matrix or the scattering matrix may be calculated from the circuit parameters.

### First Comparative Example

As a first comparative example, it is considered to optimize the circuit parameters of the reactance circuit 10 so that the high frequency characteristic of the reactance circuit 10 or the electronic circuit including the reactance circuit 10 is within the range of the target characteristic without performing steps S12 and S14 in FIG. 4. However, since the circuit parameters of the circuit example A of FIG. 6 and the circuit example B of FIGS. 7 and 8 are innumerable, the algorithm of optimization is complicated. In addition, a local solution may be obtained, and an optimal solution may not be obtained.

### Second Comparative Example

As a second comparative example, in FIG. 4, it is considered to use the scattering matrix instead of the admittance matrix in steps S12 and S14. However, the scattering matrix cannot represent a resistive component and a reactive component (or the conductance and susceptance components). Therefore, when the optimized scattering matrix is used to optimize the circuit parameters, the circuit parameters may not be optimized unless an active element including a gain and/or a resistance element including a loss is/are used as the elements of the reactance circuit 10.

According to the first embodiment, as in step S10 of FIG. 4, the acquisition unit 22 acquires the condition for calculating the admittance matrix (first matrix) of the reactance circuit 10. As in step S12, the calculation unit 24 calculates a first matrix including the admittance matrix in which i is an integer of 1 to N, j is an integer of 1 to N, θij is −π/2 or +π/2, and the element is represented by Yij=Yij×exp (θij), based on the condition acquired by the acquisition unit 22. This enables the design of the reactance circuit 10 using only the reactance element without using elements including the gain and the loss such as the active element and the resistance element.

Although the first embodiment describes an example including the admittance matrix as the first matrix, the first matrix may include the impedance matrix which is the Z parameter. The elements of the impedance matrix are represented by Zij. The elements of the first matrix are expressed by Γij=Γij×exp (θij). For the admittance matrix, Γij=Yij is satisfied, and for the impedance matrix, Γij=Zij is satisfied.

In the reactance circuit 10, since the ports Pi and Pj are symmetric, Γij=Γji is satisfied. This can reduce the number of parameters to be calculated.

As illustrated in FIG. 5, the calculation unit 24 sets the condition for the optimization as an objective function and calculates the first matrix by optimizing the first matrix. This allows the first matrix to be optimized.

In step S16 of FIG. 4, the calculation unit 24 calculates the circuit parameters of the reactance circuit 10 based on the calculated first matrix. This can suppress the algorithm for calculating the circuit parameters from becoming more complex. Moreover, it is possible to suppress the circuit parameters from becoming the local solution.

As in the circuit example B of FIGS. 7 and 8, the reactance circuit 10 has N sub-reactance circuits Ri each having a first end connected to the port Pi and a second end connected to a common node. At this time, each sub-reactance circuit Ri includes one or a plurality of reactance elements ω1 to ωM alternately series-connected and shunt-connected between the first end and the second end. The circuit parameters are the number of reactance elements ω1 to ωM in each sub-reactance circuit Ri and the reactance values of the reactance elements ω1 to ωM. This can reduce the number of circuit parameters. When the number of reactance elements in each of the sub-reactance circuits R1 to RN is one, one reactance element is series-connected or shunt-connected between the first end and the second end.

### Second Embodiment

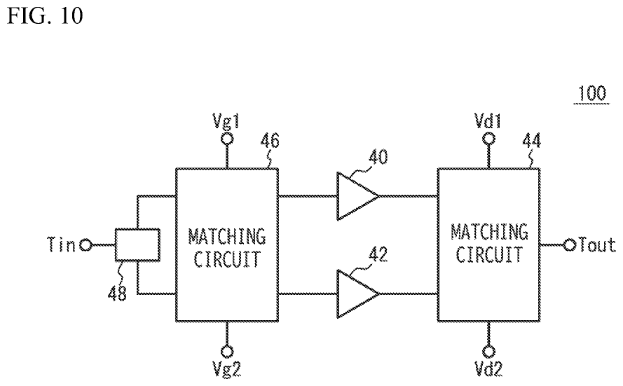

A second embodiment is an example of calculating the circuit parameters of the matching circuit of the amplifier circuit using the calculation method of the first embodiment. FIG. 10 is a circuit diagram illustrating a Doherty amplifier circuit according to the second embodiment.

### [Description of Doherty Amplifier]

As illustrated in FIG. 10, in a Doherty amplifier 100, a main amplifier 40 and a peak amplifier 42 are connected in parallel between an input terminal Tin and an output terminal Tout. A high frequency signal is input to the input terminal Tin as an input signal. When the Doherty amplifier is used in a base station of mobile communication, the frequency of the high frequency signal is, for example, 0.5 GHz or more and 10 GHz or less. A distributor 48 distributes the input signal input to the input terminal Tin to a plurality of signals. The distributor 48 is, for example, a Wilkinson type distributor.

Distributed signals passes through a matching circuit 46 and are input to the main amplifier 40 and the peak amplifier 42. The matching circuit 46 matches impedances viewed from the distributor 48 to the matching circuit 46 with impedances seen from the matching circuit 46 to the main amplifier 40 and the peak amplifier 42. The matching circuit 46 supplies gate bias voltages Vg1 and Vg2 to the gates of the main amplifier 40 and the peak amplifier 42, respectively. The main amplifier 40 and the peak amplifier 42 amplify signals and output the amplified signals, respectively. A matching circuit 44 matches impedances viewed from the main amplifier 40 and the peak amplifier 42 to the matching circuit 44 with an impedance viewed from the matching circuit 44 to the output terminal Tout. The matching circuit 44 supplies the drain bias voltages Vd1 and Vd2 to the drains of the main amplifier 40 and the peak amplifier 42, respectively.

The main amplifier 40 and the peak amplifier 42 are, for example, field effect transistors (FETs), and each of the main amplifier 40 and the peak amplifier 42 has a grounded source, a gate to which a high frequency signal is input, and a drain from which a signal is output. The FET is, for example, a GaN HEMT (Gallium Nitride High Electron Mobility Transistor) or an LDMOS (Laterally Diffused Metal Oxide Semiconductor). The main amplifier 40 and the peak amplifier 42 may be provided with multi-stage FETs, respectively. The main amplifier 40 and the peak amplifier 42 may have the same size (e.g., the gate width of the FET) or may have different sizes.

The main amplifier 40 operates in class AB or class B, and the peak amplifier 42 operates in class C. When the input power of the input signal is small, the main amplifier 40 mainly amplifies the input signal. When the input power increases, the peak amplifier 42 amplifies the peak of the input signal in addition to the main amplifier 40. Thereby, the main amplifier 40 and the peak amplifier 42 amplify the input signal.

The matching circuit 44 is designed so that the main amplifier 40 operates optimally at saturation power (e.g., efficiency is maximized) both when the peak amplifier 42 operates and when the peak amplifier 42 does not operate. When the input power is large and the peak amplifier 42 operates, the matching circuit 44 is designed so that the peak amplifier 42 operates optimally (e.g., efficiency is maximized) at saturation power. When the input power is small and the peak amplifier 42 does not operate, the matching circuit 44 makes the impedance viewed from the output terminal Tout to the matching circuit 44 substantially an open state.

### [Calculation of Admittance Matrix]

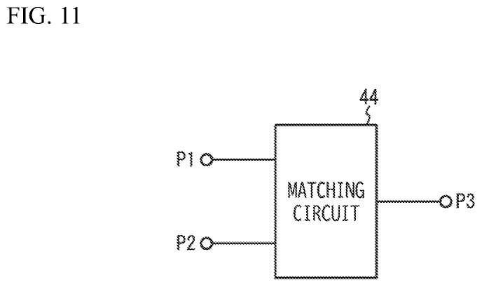

An example of calculating the admittance matrix of the matching circuit 44 will be described. FIG. 11 is a block diagram of the matching circuit for calculating the circuit parameters according to the second embodiment. As illustrated in FIG. 11, the matching circuit 44 includes ports P1 to P3. The port P1 is a port to which an output node of the main amplifier 40 is connected in FIG. 10. The port P2 is a port to which the output node of the peak amplifier 42 in FIG. 10 is connected. The port P3 is a port to which the output terminal Tout is connected in FIG. 10.

In the amplifier circuit, the high frequency characteristic at harmonic frequency may become a problem in addition to the high frequency characteristic at a fundamental frequency which is a frequency within an operation band. An example using the admittance matrix at the frequency of the fundamental wave and the admittance matrix at the frequency of a harmonic will be described. It is also possible to use only the admittance matrix of the fundamental wave without using the admittance matrix of the harmonic.

The admittance matrix of the matching circuit 44 is expressed by the following Equation 5.

$$Y = ( \begin{matrix}Y 11 & Y 12 & Y 13 \\ Y 21 & Y 22 & Y 23 \\ Y 31 & Y 32 & Y 33\end{matrix} ) \qquad [ Equation 5 ]$$

At the frequency of the fundamental wave, each of the elements Yij is represented by Equation 2 and the elements are symmetric as in Equation 3. Therefore, each element Yij in the wavy line of Equation 5 becomes a parameter. The parameters to be calculated are seven parameters including 6 parameters Y11, Y12, Y13, Y22, Y23, and Y33 and a parameter θ. It should be noted that the parameter θ is a parameter of a combination in which the phase φ of the six elements Yij is +π/2 or −π/2.

The harmonics reflected from the matching circuit 44 are problematic. Therefore, at the harmonic frequency, only the reflections at ports P1 to P3 need to be considered. Therefore, the admittance matrix of the harmonic frequency is expressed by Equation 6.

$$Y = ( \begin{matrix}Y 11 & 0 & 0 \\ 0 & Y 22 & 0 \\ 0 & 0 & Y 33\end{matrix} ) \qquad [ Equation 6 ]$$

In the harmonics, there may be a conductance component, so that the phase φ of the diagonal elements Y11, Y22 and Y33 may be other than ±π/2. Therefore, the elements of the admittance matrix are expressed using Equation 7.

Yii=Yii|<ϕii [Equation 7]

In the matching circuit 44 of FIG. 11, the parameters of the harmonic are six real numbers of |Y11|, |Y22|, |Y33|, φ11, φ22, and φ33. When the admittance matrices of a second harmonic and a third harmonic are used, the number of parameters related to the harmonics is 12 (=6×2).

In step S12 of FIG. 4, the parameters of the matrix to be calculated are 7 parameters for the fundamental wave, 6 parameters for the second harmonic, and 6 parameters for the third harmonic.

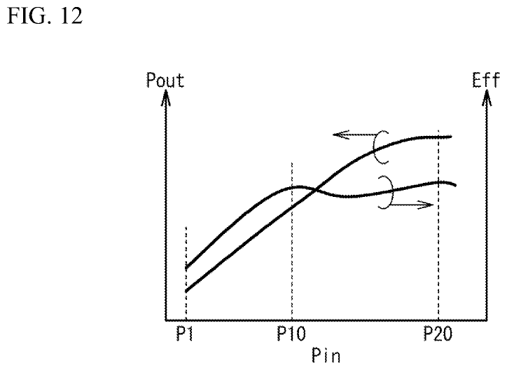

An example of the conditions to be input in step S10 of FIG. 4 will be described. FIG. 12 is a schematic diagram illustrating an output power Pout and a drain efficiency Eff with respect to an input power Pin of the Doherty amplifier according to the second embodiment. The input power Pin is a power of the fundamental wave input to the input terminal Tin. The output power Pout is a power of the fundamental wave output from the output terminal Tout. The drain efficiency Eff is represented by Eff=Pout/Pdc, where Pdc is a DC power due to a drain bias voltage.

As illustrated in FIG. 12, when the input power Pin increases, the output power Pout increases. When the input power Pin is between P1 and P10, the main amplifier 40 mainly amplifies the input signal. When the input power Pin is between P10 and P20, the main amplifier 40 and the peak amplifier 42 amplify the input signal. When the input power Pin is P20, the output power Pout is saturated. The drain efficiency Eff peaks around P10 and P20.

In step S22 of FIG. 5, the output power Pout and the drain efficiency Eff are calculated as the circuit characteristic (for example, high frequency characteristic) of the Doherty amplifier 100. The input power Pin is 20 Pi, where i is an integer from 1 to 20. Twenty output power Pout in which the input power Pin is between P1 and P20 and eleven drain efficiencies Eff in which the input power Pin is between P10 and P20 are calculated. A maximum power Pmax is a maximum output power Pout when the input power Pin is from P1 to P20. A minimum efficiency Emin is a minimum drain efficiency Eff when the input power Pin is from P10 to P20. The objective function F is defined by F=C1×Pmax+C2×Emin, where C1 and C2 are predetermined coefficients. In steps S22, S24 and S26, 7 parameters for the fundamental wave, 6 parameters for the second harmonic and 6 parameters for the third harmonic are optimized so that the objective function F is minimized. The objective function can be set as appropriate.

As an example, an optimized admittance matrix is illustrated when the frequency of the fundamental wave is 3.7 GHz, the frequency of the second harmonic is 7.4 GHz, and the frequency of the third harmonic is 11.1 GHz.

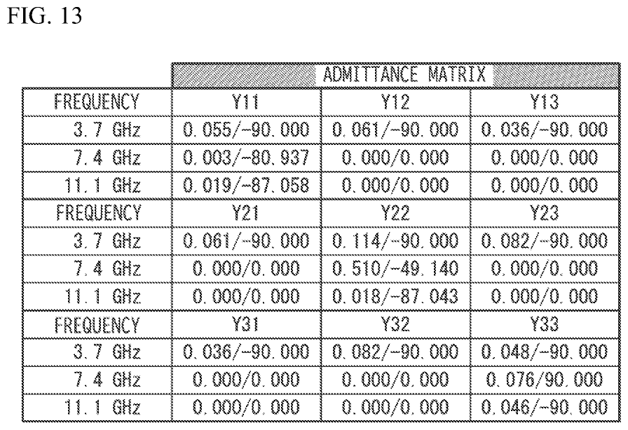

FIG. 13 is a diagram illustrating an example of the admittance matrix output in step S14 of FIG. 4. The elements of the admittance matrix for the frequency are illustrated. In each element, a part before “/” represents Yij, and a part after “/” represents the phase φ in degrees. As illustrated in FIG. 13, Yij=Yji is satisfied at 3.7 GHz of the fundamental wave. The phase φ of each element is −90° or +90°. At 7.4 GHz and 11.1 GHz of the harmonic, the elements other than diagonal elements Y11, Y22 and Y33 are 0. The phases φ of Y11 and Y22 are other than ±900.

### [Calculation of Circuit Parameter]

In the matching circuit 44, since the ports P1 to P3 are provided, the circuit example B of FIG. 7 has 3 sub-reactance circuits R1, R2 and R3. If the number M of reactance elements in FIG. 8 is fixed, the number of circuit parameters calculated in step S16 in FIG. 4 is 3× M. In step S34 of FIG. 9, the admittance matrix of each of the fundamental wave and the harmonics is calculated using 3×M circuit parameters. In steps S34, S36, and S38, 3×M circuit parameters are optimized so that the difference between the admittance matrix of each of the fundamental wave and the harmonics calculated in step S34 and the admittance matrix of FIG. 13 (the admittance matrix acquired in step S30 of FIG. 9) is minimized. In this way, the circuit parameters of the matching circuit 44 are calculated.

The admittance matrix is explained as an example of the matrix of the harmonics. In the harmonics, the phase φ does not have to be ±π/2. For this reason, the matrix of harmonics may be a scattering matrix. Equation 8 is an example of the scattering matrix used for the harmonics.

$$S = ( \begin{matrix}S 11 & 0 & 0 \\ 0 & S 22 & 0 \\ 0 & 0 & S 33\end{matrix} ) \qquad [ Equation 8 ]$$

As in Equation 8, the diagonal elements in which elements other than the diagonal elements S11, S22, and S33 are 0 are expressed using Equation 9.

Sii=|Sii|ϕii [Equation 9]

Since most of the harmonic signals are reflected at each of the ports P1 to P3, Sii is more than or equal to 0.95. Therefore, for example, it may be assumed that S11=S22=0.95 in the ports P1 and P2 connected to the amplifier is satisfied and S33=1.00 in the other ports P3 is satisfied. In this case, the parameters of the harmonics are three, namely, φ11, φ22, and φ33. When the scattering matrices of the second harmonic and the third harmonic are used, the number of parameters related to the harmonics is 3×2=6. Therefore, the number of parameters calculated in step S12 of FIG. 4 is 13, that is, 7 parameters for the fundamental wave, 3 parameters for the second harmonic, and 3 parameters for the third harmonic.

The matrices in steps S30 and S34 in FIG. 9 may be scattering matrices. The conversion from the admittance matrix to the scattering matrix is uniquely possible. For example, an example in which the admittance matrix of FIG. 13 is converted into the scattering matrix is illustrated.

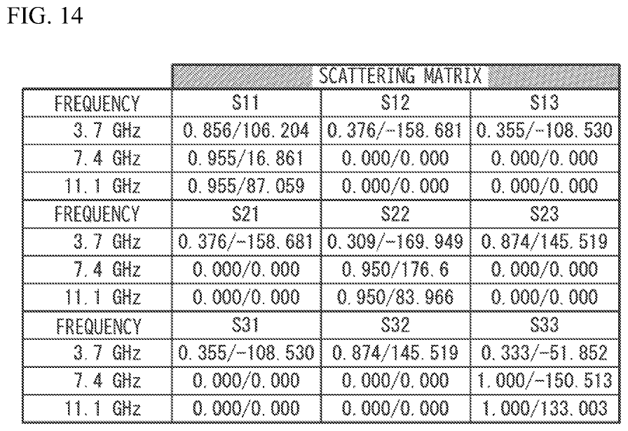

FIG. 14 is a diagram illustrating an example in which the admittance matrix of FIG. 13 is converted into the scattering matrix. The elements of the scattering matrix with respect to the frequencies are illustrated. In each element, a part before “/” represents |Sij|, and a part after “/” represents the phase φ in degrees. The phase φ of the scattering matrix is not the phase difference between the voltage and the current but a phase difference between signals.

As illustrated in FIG. 14, at 3.7 GHz of the fundamental wave, Sij=Sji is satisfied. The phase φ of each element is not limited to −90° or +90°. At 7.4 GHz and 11.1 GHz of the harmonics, the elements other than diagonal elements S11, S22 and S33 are 0. |S11| and |S22| are 0.95, and |S331 is 1.00.

As in the second embodiment, the reactance circuit 10 for calculating the circuit parameters is the matching circuit 44 used in the Doherty amplifier 100 (amplification circuit). This enables the matching circuit 44 to be designed with high accuracy. The reactance circuit 10 for calculating the circuit parameters may be the matching circuit 46. The circuit parameters of the matching circuit in an amplifier circuit other than the Doherty amplifier may be calculated.

In the amplifier circuit, the harmonics affect the high frequency characteristic. In step S12 in FIG. 4, the calculation unit 24 calculates a first matrix related to the fundamental wave and a second matrix related to the harmonics. Here, the first matrix includes the admittance matrix or the impedance matrix. The second matrix has elements that are 0 and other than the diagonal elements, and the second matrix includes the admittance matrix, the impedance matrix or the scattering matrix. This enables calculation of the circuit parameters in consideration of the harmonics. As in the first embodiment, the circuit parameters of the matching circuit 44 may be calculated using the first matrix related to the fundamental wave and without using the second matrix related to the harmonics.

The first matrix related to the fundamental wave may be an admittance matrix or an impedance matrix. The admittance is zero at open and the impedance is zero at short. The matching circuit 44 does not often short the port to ground. Therefore, the admittance matrix that can treat the port as open to the ground can be used as the first matrix.

Since the harmonic may include the resistive or the conductance component, the second matrix may be the admittance matrix, the impedance matrix, or the scattering matrix. Since the |Sii| of the harmonic is 0.95 or more, when the scattering matrix is used as the second matrix, the |Sii| can be set to a constant value, and the number of circuit parameters to be calculated can be reduced.

The respective processes (respective functions) of the above-described embodiments is realized by a processing circuit (Circuitry) including one or more processors. The processing circuit may be constituted by an integrated circuit in which one or more memories, various analog circuits, and various digital circuits are combined in addition to the one or more processors. The one or more memories store programs (commands) for causing the one or more processors to execute the respective processes. The one or more processors may execute the respective processes according to the program read from the one or more memories, or may execute the respective processes according to a logic circuit designed to execute the respective processes in advance.

The processor may be various processors suitable for control of a computer, such as CPUs, GPUs (Graphics Processing Units), DSPs (Digital Signal Processors), FPGAs (Field Programmable Gate Arrays), and ASICs (Application Specific Integrated Circuits). The plurality of physically separated processors may cooperate with each other to execute the respective processes. For example, the processors installed in a plurality of physically separated computers may cooperate with each other to execute the respective processes via a network such as a LAN (Local Area Network), a WAN (Wide Area Network), or the Internet.

The program may be installed in the memory from an external server device or the like via the network, or may be distributed in a state of being stored in a recording medium such as a CD-ROM, a DVD-ROM, or a semiconductor memory and may be installed in the memory from the recording medium.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. A calculation method executed by a computer to execute a process, the process comprising:
acquiring a condition for calculating a first matrix of a reactance circuit having N ports Pi to which a high frequency signal is input or output, wherein i is an integer of 1 to N, and N is an integer of 2 or more; and
calculating, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij).

2. The calculation method according to claim 1, wherein
Γij=Γji is satisfied in the first matrix.

3. The calculation method according to claim 1, wherein
in the calculating the first matrix, the first matrix is calculated by optimizing the first matrix with the condition as an objective function.

4. The calculation method according to claim 1, further comprising:
calculating a circuit parameter of the reactance circuit based on a calculated first matrix.

5. The calculation method according to claim 4, wherein
in sub-reactance circuits each having a first end connected to a port Pi and a second end connected to a common node, the circuit parameter includes a number of one or more reactance elements alternately series-connected and shunt-connected between the first end and the second end and a reactance value of the one or more reactance elements.

6. The calculation method according to claim 1, wherein
the reactance circuit is a matching circuit used in an amplifier circuit.

7. The calculation method according to claim 6, wherein
the first matrix includes a first matrix related to a fundamental wave which has a frequency within an operating band of the amplifier circuit, and
the calculation method further comprises calculating a second matrix related to a harmonic of the frequency, the second matrix having elements that are 0 and other than diagonal elements, the second matrix including an admittance matrix, an impedance matrix, or a scattering matrix.

8. The calculation method according to claim 1, wherein
the first matrix is the admittance matrix.

9. A calculation device comprising:
a memory; and
a processor coupled to the memory and the processor configured to:
acquire a condition for calculating a first matrix of a reactance circuit having N ports Pi to which a high frequency signal is input or output, wherein i is an integer of 1 to N, and N is an integer of 2 or more; and
calculate, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij).

10. The calculation device according to claim 9, wherein
Γij=Γji is satisfied in the first matrix.

11. The calculation device according to claim 9, wherein
the processor calculates the first matrix by optimizing the first matrix with the condition as an objective function.

12. The calculation device according to claim 9, wherein
the processor calculates a circuit parameter of the reactance circuit based on a calculated first matrix.

13. The calculation device according to claim 12, wherein
in sub-reactance circuits each having a first end connected to a port Pi and a second end connected to a common node, the circuit parameter includes a number of one or more reactance elements alternately series-connected and shunt-connected between the first end and the second end and a reactance value of the one or more reactance elements.

14. The calculation device according to claim 9, wherein
the reactance circuit is a matching circuit used in an amplifier circuit.

15. The calculation device according to claim 14, wherein
the first matrix includes a first matrix related to a fundamental wave which has a frequency within an operating band of the amplifier circuit, and
the processor calculates a second matrix related to a harmonic of the frequency, the second matrix having elements that are 0 and other than diagonal elements, the second matrix including an admittance matrix, an impedance matrix, or a scattering matrix.

16. The calculation device according to claim 9, wherein
the first matrix is the admittance matrix.

17. A non-transitory tangible computer-readable storage medium having stored therein a program for causing a computer to execute a process, the process comprising:
acquiring a condition for calculating a first matrix of a reactance circuit having N ports Pi to which a high frequency signal is input or output, wherein i is an integer of 1 to N, and N is an integer of 2 or more; and
calculating, based on the condition, the first matrix including an admittance matrix or an impedance matrix, wherein j is an integer of 1 to N, θij is −π/2 or +π/2, and an element Γij of the admittance matrix or the impedance matrix is represented by Γij=Γij×exp (θij).
